(19) United States
(12) Patent Application Publication
(10) Pub. No.: US 2026/0213140 A1
(43) Pub. Date: Jul. 23, 2026

(54) SUBSTRATE PROCESSING APPARATUS AND METHOD FOR OPERATING SUBSTRATE PROCESSING APPARATUS

(71) Applicant: Tokyo Electron Limited, Tokyo (JP)

(72) Inventors: Takuya HARASHIMA, Miyagi (JP); Hayato SAKAI, Miyagi (JP)

(73) Assignee: Tokyo Electron Limited, Tokyo (JP)

(21) Appl. No.: 19/570,709

(22) Filed: Mar. 18, 2026

Related U.S. Application Data
(63) Continuation of application No. PCT/JP2024/033291, filed on Sep. 18, 2024.

(30) Foreign Application Priority Data
Sep. 28, 2023 (JP) 2023-166756

(51) Int. Cl. H01J 37/32

(52) U.S. Cl. CPC H01J 37/32834; H01J 37/32449; H01J 2237/002

(57) ABSTRACT

A disclosed substrate processing apparatus includes a chamber, a gas supply, and an exhaust system. The gas supply is configured to supply gas into the chamber. The exhaust system is configured to exhaust gas in the chamber. The exhaust system includes a first exhaust device and a second exhaust device. The first exhaust device is connected to the chamber. The second exhaust device is connected to the chamber via the first exhaust device. The first exhaust device includes an adsorption surface and a flow passage. The adsorption surface is configured to adsorb gas from the chamber by being cooled. The flow passage is configured such that a refrigerant for cooling the adsorption surface flows therein.

### CROSS-REFERENCE TO RELATED APPLICATIONS

This application is a continuation application of PCT Application No. PCT/JP2024/033291, filed on Sep. 18, 2024, which claims the benefit of priority from Japanese Patent Application No. 2023-166756, filed on Sep. 28, 2023. The entire contents of the above listed PCT and priority applications are incorporated herein by reference.

### BACKGROUND

### Field

Example embodiments of the present disclosure relate to a substrate processing apparatus and a method of operating a substrate processing apparatus.

### Description of the Related Art

A substrate processing apparatus is used in substrate processing. The substrate processing apparatus includes a chamber, a gas supply, and an exhaust unit. The gas supply supplies gas into the chamber. The exhaust unit exhausts gas in the chamber. Japanese Unexamined Patent Publication No. 2008-192644 discloses, as a substrate processing apparatus, a plasma processing apparatus including a turbomolecular pump connected to a chamber and a dry pump connected to the chamber via the turbomolecular pump.

### SUMMARY

In one example embodiment, a substrate processing apparatus is provided. The substrate processing apparatus includes a chamber, a gas supply, and an exhaust system. The gas supply is configured to supply gas into the chamber. The exhaust system is configured to exhaust gas in the chamber. The exhaust system includes a first exhaust device and a second exhaust device. The first exhaust device is connected to the chamber. The second exhaust device is connected to the chamber via the first exhaust device. The first exhaust device includes an adsorption surface and a flow passage. The adsorption surface is configured to adsorb gas from the chamber by being cooled. The flow passage is configured such that a refrigerant for cooling the adsorption surface flows therein.

### BRIEF DESCRIPTION OF THE DRAWINGS

FIG. 1 is a diagram illustrating a configuration example of a plasma processing system.

FIG. 2 is a diagram illustrating a configuration example of a capacitively coupled plasma processing apparatus.

FIG. 3 is a diagram illustrating a substrate processing apparatus according to one example embodiment.

FIG. 4 is a diagram illustrating a first exhaust device of a substrate processing apparatus according to one example embodiment.

FIG. 5 is a flowchart of a method of operating a substrate processing apparatus according to one example embodiment.

### DETAILED DESCRIPTION

Hereinafter, various example embodiments will be described in detail with reference to the drawings. In the drawings, the same or equivalent portions are denoted by the same reference signs.

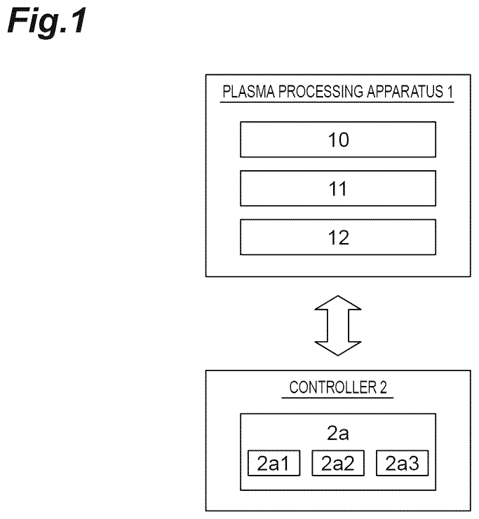

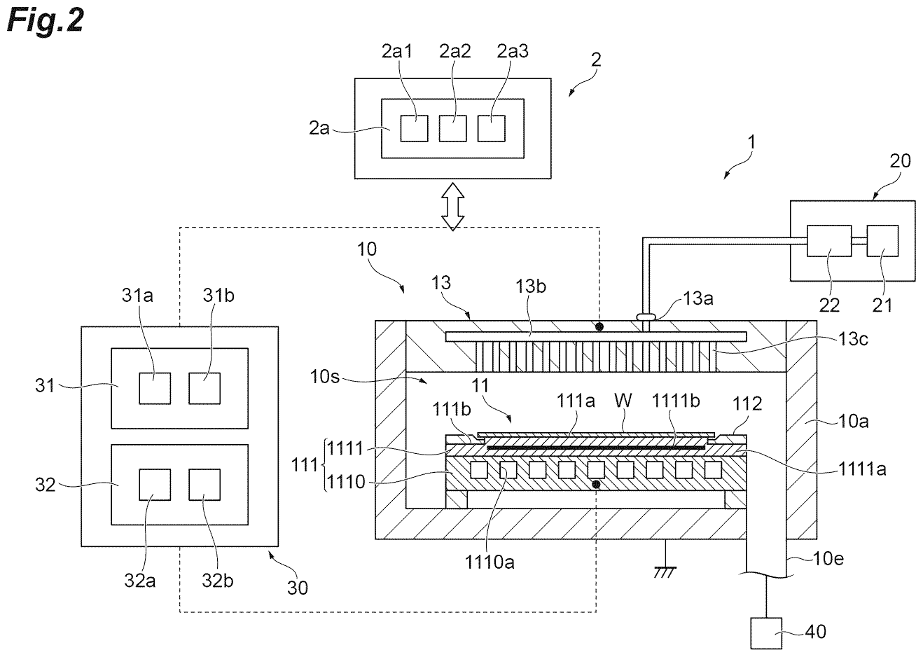

First, a plasma processing apparatus, which is a substrate processing apparatus according to one example embodiment, will be described with reference to FIGS. 1 and 2.

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in the plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, an AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulating member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 1110 and the at least one RF/DC electrode may each function as a lower electrode. The electrostatic electrode 1111b may also function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, and one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include at least one flow modulation device that can modulate or pulse the flow of the at least one process gas.

The electric power source 30 includes an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses may have a rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby function as a voltage pulse generator. In the case that the second DC generator 32b and the waveform generator function as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

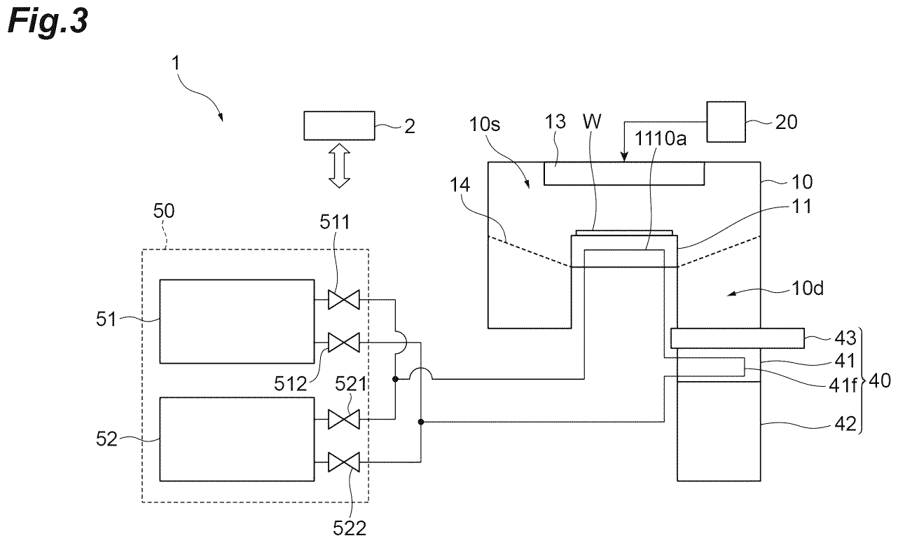

Hereinafter, reference is made to FIG. 3. FIG. 3 is a diagram illustrating a substrate processing apparatus according to one example embodiment. In one embodiment, the gas supply 20 may be configured to selectively supply a first gas and a second gas to the plasma processing space 10s. The first gas is a process gas for processing the substrate W in the plasma processing space 10s. The first gas may include hydrogen fluoride.

The first gas may further include a phosphorus-containing gas. The phosphorus-containing gas may be a phosphorus halide gas. In one embodiment, the phosphorus halide gas may be a phosphorus fluoride gas including fluorine as a halogen element, such as a PF₃ gas and/or a PF₅ gas. In one embodiment, the phosphorus halide gas may be a phosphorus chloride gas including chlorine as a halogen element, such as a PCl₃ gas and/or a PCl₅ gas. In one embodiment, the phosphorus halide gas may be a gas including bromine or iodine as a halogen element, such as a PBr₃ gas, a PBr₅ gas, or a PI₃ gas. In one embodiment, the phosphorus halide gas may be a gas including two or more halogen elements, such as a PClF₂ gas, a PCl₂F gas, or a PCl₂F₃ gas. In one embodiment, the phosphorus halide gas may be a phosphorus oxyhalide gas, and may be a phosphorus oxyfluoride gas or a phosphorus oxychloride gas. For example, the phosphorus halide gas may be a POF₃ gas, a POCl₃ gas, a POF₂Cl₂ gas, a POFCl₂ gas, or a POF₂Cl gas.

The first gas may further include at least one selected from the group consisting of a carbon-containing gas, a halogen-containing gas, and an oxygen-containing gas. The carbon-containing gas may be at least one selected from the group consisting of a fluorocarbon gas, a hydrofluorocarbon gas, and a hydrocarbon gas. In one embodiment, the carbon-containing gas may be at least one fluorocarbon gas selected from the group consisting of CF₄, C₂F₂, C₂F₄, C₃F₈, C₄F₆, C₄F₈, and C₅F₈. In one embodiment, the carbon-containing gas may be at least one hydrofluorocarbon gas selected from the group consisting of CHF₃, CH₂F₂, CH₃F, C₂HF₅, C₂H₂F₄, C₂H₃F₃, C₂H₄F₂, C₃HF₇, C₃H₂F₂, C₃H₂F₆, C₃H₂F₄, C₃H₃F₅, C₄H₅F₅, C₄H₂F₆, C₅H₂F₁₀, and C₅H₃F₇. In one embodiment, the carbon-containing gas may be at least one hydrocarbon gas selected from the group consisting of CH₄, C₂H₆, C₃H₆, C₃H₈, and C₄H₁₀.

The halogen-containing gas may be a gas including a halogen other than fluorine, or may be a gas including fluorine and a halogen other than fluorine. In one embodiment, the halogen-containing gas is a chlorine-containing gas such as Cl₂, HCl, BCl₃, or ClF₃. In one embodiment, the halogen-containing gas is a bromine-containing gas such as Br₂, HBr, or BrF₃. In one embodiment, the halogen-containing gas is an iodine-containing gas such as HI, IF₅, or IF₇. The halogen-containing gas may be a halogen-containing gas including carbon, such as CHₓCl_{y}, CFₓBr_{y}, or CFₓI_{y}. Here, x and y are each a natural number of 1 or more.

The oxygen-containing gas may be, for example, at least one selected from the group consisting of O₂, CO, CO₂, H₂O, and H₂O₂.

The first gas may be used in plasma etching of a film of the substrate W. That is, plasma may be generated from the first gas by the plasma generator 12, and the substrate W may be processed by chemical species such as ions and/or radicals from the plasma.

The second gas is a gas different from the first gas. The second gas may be a cleaning gas for cleaning a surface in the chamber 10 after substrate processing using the first gas. The second gas may be used in plasma cleaning. That is, plasma may be generated from the second gas by the plasma generator 12, and the surface in the chamber 10 may be cleaned by chemical species such as ions and/or radicals from the plasma.

As illustrated in FIG. 3, in one embodiment, a space in the chamber 10 may include a plasma processing space 10s and an exhaust space 10d. The plasma processing apparatus 1 may further include a baffle member 14 interposed between the plasma processing space 10s and the exhaust space 10d. The plasma processing space 10s is located above the baffle member 14, and the exhaust space 10d is located below the baffle member 14. The baffle member 14 provides a plurality of through holes connecting the plasma processing space 10s and the exhaust space 10d. The baffle member 14 extends between the substrate support 11 and a sidewall of the chamber 10.

The exhaust system 40 includes a first exhaust device 41 and a second exhaust device 42. The exhaust system 40 may further include a pressure regulator 43. The pressure regulator 43 may be a pressure regulating valve.

The first exhaust device 41 is connected to the chamber 10 (for example, the exhaust space 10d). The first exhaust device 41 may be connected to the chamber 10 via the pressure regulator 43. The second exhaust device 42 is connected to the chamber 10 (for example, the exhaust space 10d) via the first exhaust device 41. The second exhaust device 42 may be a turbomolecular pump or a mechanical booster pump.

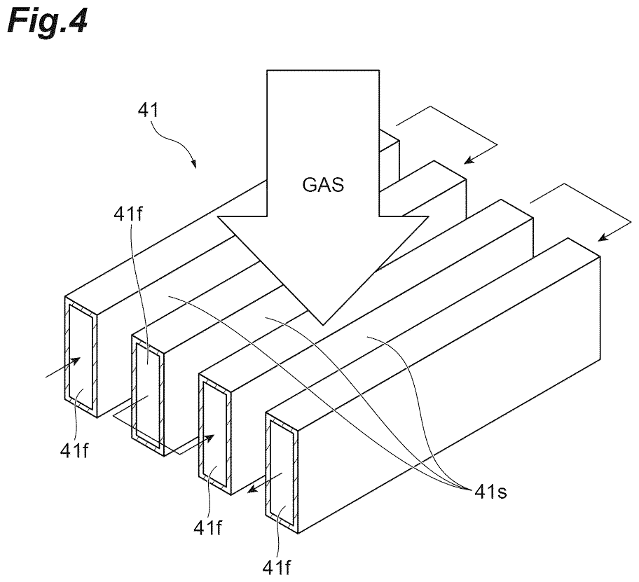

Hereinafter, reference is made to FIG. 4 together with FIG. 3. FIG. 4 is a diagram illustrating a first exhaust device of a substrate processing apparatus according to one example embodiment. The first exhaust device 41 includes a container, an adsorption surface 41s disposed in the container, and a flow passage 41f. The adsorption surface 41s is configured to cool gas from the chamber 10. The adsorption surface 41s may be provided by each of a plurality of plate-shaped bodies (or a plurality of fins). As illustrated in FIG. 4, the plurality of plate-shaped bodies are alternately arranged with a plurality of gaps. The plurality of plate-shaped bodies may be arranged substantially parallel to each other.

The flow passage 41f passes through the plurality of plate-shaped bodies. As indicated by arrows in FIG. 4, the flow passage 41f may include portions extending between adjacent plate-shaped bodies. As indicated by arrows in FIG. 4, a refrigerant for cooling the adsorption surface 41s flows through the flow passage 41f. Gas from the chamber 10 flows through an interior of the container of the first exhaust device 41 toward the second exhaust device 42. In the container of the first exhaust device 41, the gas flows into the plurality of gaps provided by the plurality of plate-shaped bodies. When the gas contacts the adsorption surface 41s in the container of the first exhaust device 41, the gas is cooled and liquefied, and is adsorbed onto the adsorption surface 41s.

As illustrated in FIG. 3, in one embodiment, the plasma processing apparatus 1 may further include a supply device 50 configured to supply a refrigerant to the flow passage 41f. The supply device 50 may be configured to supply a heating medium to the flow passage 41f in addition to the refrigerant. The supply device 50 may include a refrigerant supplier 51 that supplies the refrigerant and a heating medium supplier 52 that supplies the heating medium. The supply device 50 may include a valve 511, a valve 512, a valve 521, and a valve 522.

A refrigerant output port of the refrigerant supplier 51 is connected to one end of the flow passage 41f via the valve 511. A refrigerant recovery port of the refrigerant supplier 51 is connected to the other end of the flow passage 41f via the valve 512. A heating medium output port of the heating medium supplier 52 is connected to one end of the flow passage 41f via the valve 521. A heating medium recovery port of the heating medium supplier 52 is connected to the other end of the flow passage 41f via the valve 522. When the valve 511 and the valve 512 are opened and the valve 521 and the valve 522 are closed, the refrigerant is supplied from the refrigerant supplier 51 to the flow passage 41f and is returned from the flow passage 41f to the refrigerant supplier 51. When the valve 511 and the valve 512 are closed and the valve 521 and the valve 522 are opened, the heating medium is supplied from the heating medium supplier 52 to the flow passage 41f and is returned from the flow passage 41f to the heating medium supplier 52.

In one embodiment, the refrigerant output port of the refrigerant supplier 51 may be connected to one end of the flow passage 41f via a flow passage 1110a of the substrate support 11. The heating medium output port of the heating medium supplier 52 may be connected to one end of the flow passage 41f via the flow passage 1110a. Alternatively, the refrigerant output port of the refrigerant supplier 51 and the heating medium output port of the heating medium supplier 52 may be connected to one end of the flow passage 41f without going through the flow passage 1110a. In this case, a refrigerant and/or a heating medium may be supplied to the flow passage 1110a from a supply device separate from the supply device 50.

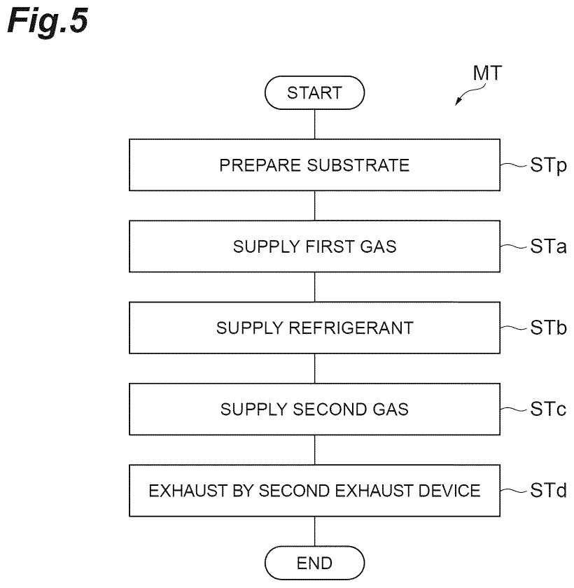

Hereinafter, a method of operating a substrate processing apparatus according to one example embodiment will be described with reference to FIG. 5. FIG. 5 is a flowchart of a method of operating a substrate processing apparatus according to one example embodiment. An operation method illustrated in FIG. 5 (hereinafter referred to as “method MT”) can be applied to the plasma processing apparatus 1. In the method MT, each unit of the plasma processing apparatus 1 can be controlled by the controller 2. Hereinafter, control by the controller 2 in operation of the plasma processing apparatus 1 will also be described.

The method MT may be started in step STp. In step STp, the substrate W is prepared on the substrate support 11. In the method MT, step STa is then performed. In step STa, the first gas is supplied from the gas supply 20 into the chamber 10. In step STa, the controller 2 controls the gas supply 20 to supply the first gas having a specified flow rate into the chamber 10. A flow rate of the first gas in step STa may be larger than a flow rate of the second gas in step STc described below. The flow rate of the first gas in step STa may be a flow rate at which a pressure in the chamber 10 cannot reach a target pressure when the second exhaust device 42 is used alone. On the other hand, the flow rate of the second gas in step STc may be a flow rate at which the pressure in the chamber 10 can reach the target pressure even when the second exhaust device 42 is used alone.

In step STa, plasma may be generated from the first gas in the chamber 10. In this case, the controller 2 controls the plasma generator 12 to generate plasma from the first gas. For example, the controller 2 may control the first RF generator 31a in step STa. In step STa, an electric bias may be supplied to a lower electrode of the substrate support 11 to attract ions from the plasma generated from the first gas to the substrate W. The electric bias may be the bias RF signal or the pulsed first DC signal described above. In this case, in step STa, the controller 2 controls the second RF generator 31b or the first DC generator 32a.

Step STb is performed during a period in which step STa is executed. In step STb, gas in the chamber 10 is exhausted using the first exhaust device 41. In step STb, gas from the chamber 10 is adsorbed onto the adsorption surface 41s of the first exhaust device 41. Therefore, in step STb, the refrigerant is supplied from the supply device 50 to the flow passage 41f. The refrigerant may be supplied to the flow passage 41f via the flow passage 1110a. A temperature of the refrigerant supplied to the flow passage 41f may be set to 0° C. or lower. When the first gas contains hydrogen fluoride, the temperature of the refrigerant supplied to the flow passage 41f may be −70° C. or lower to adsorb hydrogen fluoride onto the adsorption surface 41s. In step STb, gas in the chamber 10 may be exhausted using the second exhaust device 42 together with the first exhaust device 41.

In step STb, the controller 2 controls the supply device 50 to supply the refrigerant having a specified temperature to the flow passage 41f. In one embodiment, the controller 2 may control the supply device 50 to cause the refrigerant supplier 51 to supply the refrigerant, open the valve 511 and the valve 512, and close the valve 521 and the valve 522. In step STb, the controller 2 may also control the second exhaust device 42 to perform exhausting by the second exhaust device 42.

Next, step STc is performed. Step STc is performed after the substrate W is processed in step STa. After step STa and before step STc, the substrate W may be transferred out from an interior of the chamber 10 to an exterior of the chamber 10. In step STc, the second gas is supplied from the gas supply 20 into the chamber 10. In step STc, the controller 2 controls the gas supply 20 to supply the second gas having a specified flow rate into the chamber 10. The second gas may be a cleaning gas for cleaning a surface in the chamber 10.

In step STc, plasma may be generated from the second gas in the chamber 10. In this case, the controller 2 controls the plasma generator 12 to generate plasma from the second gas. For example, the controller 2 may control the first RF generator 31a in step STc.

Step STd is performed during a period in which step STc is performed. In step STd, gas in the chamber 10 and gas desorbed from the adsorption surface 41s by vaporization are exhausted by the second exhaust device 42. In step STd, a heating medium may be supplied from the supply device 50 to the flow passage 41f. The heating medium may be supplied to the flow passage 41f via the flow passage 1110a.

In step STd, the controller 2 controls the second exhaust device 42 to perform exhausting by the second exhaust device 42. In step STd, the controller 2 may control the supply device 50 to supply the heating medium having a specified temperature to the flow passage 41f. In one embodiment, the controller 2 may control the supply device 50 to cause the heating medium supplier 52 to supply the heating medium, close the valve 511 and the valve 512, and open the valve 521 and the valve 522.

As described above, in the plasma processing apparatus 1, it is possible to exhaust a relatively large flow rate of gas by the first exhaust device 41. After using the first exhaust device 41, it is possible to desorb gas from the adsorption surface 41s and exhaust the gas by the second exhaust device 42. When the heating medium is supplied to the flow passage 41f, it is possible to promote desorption of gas from the adsorption surface 41s.

Although various example embodiments have been described above, various additions, omissions, substitutions, and changes may be made without being limited to the example embodiments described above. It is also possible to combine elements in different embodiments to form other embodiments.

The substrate processing apparatus according to the example embodiment described above is a plasma processing apparatus, but the content of the present disclosure is also applicable to a substrate processing apparatus different from a plasma processing apparatus.

Here, various example embodiments included in the present disclosure are described in [E1] to [E20] below.
E1

### A Substrate Processing Apparatus Including:

a chamber;
a gas supply configured to supply gas into the chamber; and
an exhaust system configured to exhaust gas in the chamber,
wherein the exhaust system includes:
   a first exhaust device connected to the chamber; and
   a second exhaust device connected to the chamber via the first exhaust device, and
the first exhaust device includes:
   an adsorption surface configured to adsorb gas from the chamber by being cooled; and
   a flow passage configured such that a refrigerant for cooling the adsorption surface flows therein.
E2

The substrate processing apparatus according to E1, further including a supply device connected to the flow passage and configured to supply the refrigerant to the flow passage.
E3

The substrate processing apparatus according to E2, wherein the supply device is configured to supply a heating medium to the flow passage.
E4

The substrate processing apparatus according to E2 or E3, further including a substrate support disposed in the chamber,
wherein the supply device is further connected to a flow passage in the substrate support.
E5

The substrate processing apparatus according to E4, wherein the supply device is connected to the flow passage of the first exhaust device via the flow passage in the substrate support.
E6

The substrate processing apparatus according to any one of E2 to E5, wherein the gas supply is configured to supply, into the chamber, a first gas for processing a substrate in the chamber.
E7

The substrate processing apparatus according to E6, wherein the gas supply is configured to supply a second gas different from the first gas into the chamber.
E8

The substrate processing apparatus according to E7, further including a controller,
wherein the controller is configured to:
   (a) control the gas supply to supply the first gas into the chamber;
   (b) control the supply device to supply the refrigerant to the flow passage of the first exhaust device during a period of the (a);
   (c) control the gas supply to supply the second gas into the chamber after the substrate is processed in the chamber in the (a); and
   (d) control the second exhaust device to exhaust gas in the chamber and gas desorbed from the adsorption surface by vaporization during a period of the (c).
E9

The substrate processing apparatus according to E8, wherein a flow rate of the first gas in the (a) is larger than a flow rate of the second gas in the (c).
E10

The substrate processing apparatus according to E8 or E9, wherein the controller is configured to control the supply device to adjust a temperature of the refrigerant supplied to the flow passage of the first exhaust device in the (b) to a temperature of 0° C. or lower.
E11

The substrate processing apparatus according to E10,
wherein the first gas includes hydrogen fluoride, and
the controller is configured to control the supply device to adjust a temperature of the refrigerant supplied to the flow passage of the first exhaust device in the (b) to a temperature of −70° C. or lower.
E12

The substrate processing apparatus according to E11, wherein the first gas further includes a phosphorus-containing gas.
E13

The substrate processing apparatus according to any one of E7 to E12, wherein the second gas is a cleaning gas for cleaning a surface in the chamber.
E14

The substrate processing apparatus according to any one of E6 to E13, wherein the substrate processing apparatus is a plasma processing apparatus and further includes a plasma generator configured to generate plasma from the first gas.
E15

The substrate processing apparatus according to any one of E1 to E14, wherein the second exhaust device is a turbomolecular pump or a mechanical booster pump.
E16

A method of operating a substrate processing apparatus, the substrate processing apparatus including:
a chamber;
a gas supply configured to supply gas into the chamber; and
an exhaust system configured to exhaust gas in the chamber,
wherein the exhaust system includes:
   a first exhaust device connected to the chamber; and
   a second exhaust device connected to the chamber via the first exhaust device, and
the first exhaust device includes:
   an adsorption surface configured to adsorb gas from the chamber by being cooled; and
   a flow passage configured such that a refrigerant for cooling the adsorption surface flows therein,
the gas supply is configured to supply a first gas for processing a substrate in the chamber and a second gas different from the first gas into the chamber, and
the method includes:
   (a) supplying the first gas from the gas supply into the chamber;
   (b) supplying the refrigerant to the flow passage of the first exhaust device during a period of the (a);
   (c) supplying the second gas from the gas supply into the chamber after the substrate is processed in the chamber in the (a); and
   (d) exhausting gas in the chamber and gas desorbed from the adsorption surface by vaporization by the second exhaust device during a period of the (c).
E17

The method of operating a substrate processing apparatus according to E16, wherein a temperature of the refrigerant supplied to the flow passage of the first exhaust device in the (b) is 0° C. or lower.
E18

The method of operating a substrate processing apparatus according to E17,
wherein the first gas includes hydrogen fluoride, and
a temperature of the refrigerant supplied to the flow passage of the first exhaust device in the (b) is −70° C. or lower.
E19

The method of operating a substrate processing apparatus according to E18, wherein the first gas further includes a phosphorus-containing gas.
E20

The method of operating a substrate processing apparatus according to any one of E16 to E19, wherein the second gas is a cleaning gas for cleaning a surface in the chamber.

From the above description, it will be understood that various embodiments of the present disclosure have been described herein for purposes of illustration, and that various modifications may be made without departing from the scope and spirit of the present disclosure. Accordingly, the various embodiments disclosed herein are not intended to be limiting, and the true scope and spirit are indicated by the appended claims.

What is claimed is:

1. A substrate processing apparatus comprising:
a chamber;
a gas supply configured to supply gas into the chamber; and
an exhaust system configured to exhaust gas in the chamber,
wherein the exhaust system includes:
a first exhaust device connected to the chamber; and
a second exhaust device connected to the chamber via the first exhaust device, and
the first exhaust device includes:
an adsorption surface configured to adsorb gas from the chamber by being cooled; and
a flow passage configured such that a refrigerant for cooling the adsorption surface flows therein.

2. The substrate processing apparatus according to claim 1, further comprising:
a supply device connected to the flow passage and configured to supply the refrigerant to the flow passage.

3. The substrate processing apparatus according to claim 2, wherein
the supply device is configured to supply a heating medium to the flow passage.

4. The substrate processing apparatus according to claim 2, further comprising:
a substrate support in the chamber,
wherein the supply device is further connected to a flow passage in the substrate support.

5. The substrate processing apparatus according to claim 4, wherein
the supply device is connected to the flow passage of the first exhaust device via the flow passage in the substrate support.

6. The substrate processing apparatus according to claim 2, wherein
the gas supply is configured to supply, into the chamber, a first gas for processing a substrate in the chamber.

7. The substrate processing apparatus according to claim 6, wherein
the gas supply is configured to supply a second gas different from the first gas into the chamber.

8. The substrate processing apparatus according to claim 7, further comprising:
a controller configured to:
control the gas supply to supply the first gas into the chamber;
control the supply device to supply the refrigerant to the flow passage of the first exhaust device during a period of the control of the gas supply to supply the first gas into the chamber;
control the gas supply to supply the second gas into the chamber after the substrate is processed in the chamber during the control of the gas supply to supply the first gas into the chamber; and
control the second exhaust device to exhaust gas in the chamber and gas desorbed from the adsorption surface by vaporization during a period of the control of the gas supply to supply the second gas into the chamber.

9. The substrate processing apparatus according to claim 8, wherein
a flow rate of the first gas during the control of the gas supply to supply the first gas into the chamber is larger than a flow rate of the second gas in the control of the gas supply to supply the second gas into the chamber.

10. The substrate processing apparatus according to claim 8, wherein
the controller is configured to control the supply device to adjust a temperature of the refrigerant supplied to the flow passage of the first exhaust device during the control of the supply device to supply the refrigerant to the flow passage of the first exhaust device to a temperature of 0° C. or lower.

11. The substrate processing apparatus according to claim 10, wherein
the first gas includes hydrogen fluoride, and
the controller is configured to control the supply device to adjust a temperature of the refrigerant supplied to the flow passage of the first exhaust device during the control of the supply device to supply the refrigerant to the flow passage of the first exhaust device to a temperature of −70 ° C. or lower.

12. The substrate processing apparatus according to claim 11, wherein
the first gas further includes a phosphorus-containing gas.

13. The substrate processing apparatus according to claim 7, wherein
the second gas is a cleaning gas for cleaning a surface in the chamber.

14. The substrate processing apparatus according to claim 6, wherein
the substrate processing apparatus is a plasma processing apparatus and further comprises a plasma generator configured to generate plasma from the first gas.

15. The substrate processing apparatus according to claim 1, wherein
the second exhaust device is a turbomolecular pump or a mechanical booster pump.

16. A method of operating a substrate processing apparatus, the substrate processing apparatus comprising
a chamber;
a gas supply configured to supply gas into the chamber; and
an exhaust system configured to exhaust gas in the chamber,
wherein the exhaust system includes:
a first exhaust device connected to the chamber; and
a second exhaust device connected to the chamber via the first exhaust device, and
the first exhaust device includes:
an adsorption surface configured to adsorb gas from the chamber by being cooled; and
a flow passage configured such that a refrigerant for cooling the adsorption surface flows therein, and
the gas supply is configured to supply a first gas for processing a substrate in the chamber and a second gas different from the first gas into the chamber, and
the method comprises:
supplying the first gas from the gas supply into the chamber;
supplying the refrigerant to the flow passage of the first exhaust device during a period of the supplying the first gas from the gas supply into the chamber;
supplying the second gas from the gas supply into the chamber after the substrate is processed in the chamber during the supplying the first gas from the gas supply into the chamber; and
exhausting gas in the chamber and gas desorbed from the adsorption surface by vaporization by the second exhaust device during a period of the supplying the second gas from the gas supply into the chamber.

17. The method of operating a substrate processing apparatus according to claim 16, wherein
a temperature of the refrigerant supplied to the flow passage of the first exhaust device during the supplying the refrigerant to the flow passage of the first exhaust device is 0° C. or lower.

18. The method of operating a substrate processing apparatus according to claim 17,
wherein the first gas includes hydrogen fluoride, and
a temperature of the refrigerant supplied to the flow passage of the first exhaust device during the supplying the refrigerant to the flow passage of the first exhaust device is −70° C. or lower.

19. The method of operating a substrate processing apparatus according to claim 18, wherein
the first gas further includes a phosphorus-containing gas.

20. The method of operating a substrate processing apparatus according to claim 16, wherein
the second gas is a cleaning gas for cleaning a surface in the chamber.
